(19) United States
(12) Patent Application Publication
(10) Pub. No.: US 2024/0384037 A1
(43) Pub. Date: Nov. 21, 2024

(54) Irradiation-curable silicone composition

(71) Applicant: MOMENTIVE PERFORMANCE MATERIALS GMBH, Leverkusen (DE)

(72) Inventors: Cristian de Santis, Duisburg (DE); Andrea Ruppenthal, Leverkusen (DE)

(21) Appl. No.: 18/685,005

(22) PCT Filed: Aug. 23, 2022
(86) PCT No.: PCT/EP2022/073469

§ 371 Date: Feb. 20, 2024

Related U.S. Application Data
(60) Provisional application No. 63/236,473, filed on Aug. 24, 2021.

(51) Int. Cl. C08G 77/20; C08G 77/08; C08G 77/12; C08J 3/28; C08L 83/04

(52) U.S. Cl. CPC C08G 77/20; C08G 77/08; C08G 77/12; C08J 3/28; C08L 83/04; C08J 2383/05; C08J 2383/07; C08L 2203/206; C08L 2205/025; C08L 2205/03; C08L 2312/06

(57) ABSTRACT

The present invention relates to an irradiation-curable silicone composition, the cured compositions obtained therefrom; their use as dam and sealing material in dam and fill applications for electronic component and displays comprising the cured composition.

### TECHNICAL FIELD

The present invention relates to an irradiation-curable silicone composition, the cured compositions obtained therefrom; their use as dam and sealing material in dam and fill applications for electronic component and displays comprising the cured composition.

### BACKGROUND ART

In general, the crosslinking process in crosslinking silicone compositions is conducted by a hydrosilylation reaction in which, for example, platinum or another metal from the platinum group can be used as a catalyst. In the catalytic reaction, aliphatically unsaturated groups are reacted with Si-bonded hydrogen; thereby forming the cured composition.

In general, such compositions comprise a Si-alkenyl as component A1), a polyorganohydrogensiloxane with a SiH-bond as component B), a catalyst as component C) and additional additives like fillers as component D).

For example, US 2018/0314352 A discloses a one-component silicone material free of acrylic units which comprises a polysiloxane containing at least two alkenyl groups, a polyhydroysiloxane having on average at least two SiH groups per molecule, a silicone resin, a filler and a photoactive platinum catalyst.

The cured composition has a variety of different uses. For example, it can be used as dam material. The use of such dam material is described, for example, in WO 2018/208348. Therein the dam material is provided around the periphery of a first substrate, then a further flowable silicone is introduced onto this first substrate and a second substrate is placed on top of this assembly, thereby trapping the flowable silicone between the two substrates.

The injection of the flowable silicone in a situation in which the first and second substrate are arranged on top of each other while having a gap in between due to the presence of a dam material is also possible.

The cured compositions are, for example, used in displays, fill and dam applications, or for (micro-) electronics.

### Technical Problems

When using such cured compositions as dam materials these dam materials will be flowable to some extend before curing; i.e. after application of the dam material its height will reduce and its width will increase due to this flowability between application and curing. This can be detrimental as, due to the reduced height, the first and second substrate will be closer to one another and the dam material will have a greater width. It is desirable to have compositions with a good aspect ratio, wherein the aspect ratio refers to the ratio between the height to the width of the cured composition.

In case the cured composition is used at a location visible to a person it is often desirable that the cured composition is highly transparent and/or without any coloring; i.e. the cured composition should be “invisible” to the person.

The cured compositions will deteriorate over time; this deterioration will be highly dependent on the actual environment of the composition. Such deterioration is expressed, for example, by a decrease of the transparency and/or a change of color. Even if such a change would not affect other parameters of the composition in case the cured composition is at a location visible to a person such changes are undesirable anyway. In general, having cured compositions with high stability; i.e. cured compositions with no change in transparency and/or no change in color and/or other changes in visibility, even under harsh environment, are desirable. Preferably, the cured compositions should fulfill such a requirement at room temperature and/or at elevated temperatures and/or at elevated temperatures with humid conditions over prolonged periods of time.

These technical problems are not adequately addressed and/or solved by the state of the art.

### Solution to the Problem

The irradiation-curable silicone composition according to the current invention comprises:
A1) at least one polyorganosiloxane having at least one alkenyl group, preferably two alkenyl groups with a viscosity up to 500 Pa·s at 20° C. and a shear rate of D=10 s⁻¹,
A2) at least one linear polydiorganosiloxane, having a complex viscosity of at least 1000 Pa·s, preferably at least 2500 Pa·s, more preferably at least 5000 Pa·s, measured in the oscillation mode at 20° C., selected from the group of:
   a linear polydiorganosiloxane having no alkenyl group and
   a linear polydiorganosiloxane having at least one alkenyl group bound to a silicon atom
B) at least one polyorganohydrogensiloxane having at least one SiH group, preferably at least two SiH groups, and
C) at least one irradiation-activatable catalyst,
D) optionally one or more auxiliary components.

Unless stated otherwise viscosities mentioned herein are determined in accordance with DIN 53019 and, in general, they are measured at a shear rate of D=10 s⁻¹ at 20° C.

Unless stated otherwise, the complex viscosity is measured at 20° C. in accordance with known procedures in oscillation mode at 1 Hz and with 1% deformation (see for example: https://www.tracomme.ch/wordpress/wp-content/uploads/2018/07/V279-e-IQ-Performing-Theological-tests-in-o-the-HAAKE-Viscotester-IQ.pdf.

Specific viscosity ranges are meant to comprise both end-point.

The complex viscosity is the frequency-dependent viscosity function determined during forced harmonic oscillation of shear stress (see http://www1.Isbu.ac.uk/water/rheology.html). When an oscillating force is applied to a material the shear strain rate lags behind the changes in the causative force by a phase angle φ. This means φ is zero for an ideally elastic gel and 90° for an ideally viscous liquid.

The complex viscosity is defined as follows: complex viscosity=viscosity−i*elasticity;
wherein “i” refers to the imaginary unit (i²⁼⁻¹);
tan (φ)=elasticity/viscosity; wherein φ is the phase angle.

### Component A1

The inventive composition comprises at least one polyorganosiloxane having at least one, preferably two unsaturated hydrocarbyl residues (component A1)). Component A1) may include one or more polyorganosiloxanes having in average at least two alkenyl groups. Suitable components A1) can be described by the general formula (Ia),

[MₐD_{b}T_{c}Q_{d}Zₑ]ₘ (Ia)

wherein the indices in formula (Ia) represent the ratios of the siloxy units M, D, T and Q, which can be distributed blockwise or randomly in the polysiloxane. Within a polysiloxane each siloxane unit can be identical or different and
a=0-10
b=0-2000
c=0-50
d=0-1
e=0-300
m=1-1000
   with a, b, c, d and m being such that the viscosity of component A1) at 20° C. is less than 500 Pa·s (measured at a shear rate of D=10 s⁻¹ at 20° C.). The viscosity of component A1) refers to the viscosity of a single component A1) or a mixture of components A1).

In the formula (Ia):
M=R₃SiO _{1/2}, or M*
D=R₂SiO₂₂, or D*
T=RSiO_{3/2}, or T*
Q=SiO_{4/2},
divalent Z, which are bridging groups between siloxy groups above,
   with the proviso that there is at least one group selected from M*, D* or T*,
   wherein each R, which may be the same or different, is selected from optionally substituted alkyl with up to 30 carbon atoms, optionally substituted aryl with up to 30 carbon atoms, poly (C₂-C₄)-alkylene ether with up to 1000 alkylene oxy units, the groups R being free of aliphatic unsaturation, and
   wherein M*=R¹ₚ₀R₃₋ₚ₀SiO_{1/2}, D*=R¹_{q0}R_{2-qo}SiO_{2/2}, T*=R¹SiO_{3/2},
   wherein
   p0=1-3, preferably 1,
   q0=1-2, and
   Z is as defined below.
   R is preferably selected from n-, iso, or tertiary alkyl, alkoxyalkyl, C₅-C₃₀-cyclic alkyl, or C₆-C₃₀-aryl, alkylaryl, which groups can be substituted in addition by one or more O-, N-, S- or F-atom, or poly(C₂-C₄)-alkylene ethers with up to 500 alkylene oxy units the groups R being free of aliphatic unsaturation,

Examples of suitable monovalent hydrocarbon radicals include alkyl radicals, preferably such as CH₃—, CH₃CH₂—, (CH₃)₂CH—, C₈H₁₇— and C₁₀H₂₁—, and cycloaliphatic radicals, such as cyclohexylethyl, aryl radicals, such as phenyl, tolyl, xylyl, aralkyl radicals, such as benzyl and 2-phenylethyl. Preferable monovalent halohydrocarbon radicals have the formula CₙF₂ₙ₊₁CH₂CH₂— wherein n has a value of from 1 to 10, such as, for example, CF₃CH₂CH₂—, C₄F₉CH₂CH₂—, C₆F₁₃CH₂CH₂—, C₂F₅—O(CF₂—CF₂—O)₁₋₁₀CF₂—, F[CF(CF₃)—CF₂—O]₁₋₅—(CF₂)₀₋₂—, C₃F₇—OCF(CF₃)— and C₃F₇—OCF(CF₃)—CF₂—OCF(CF₃)—.

Preferred groups for R are methyl, phenyl, 3,3,3-trifluoropropyl.

In formula (Ia) the indices should represent the average polymerisation degree Pₙ based on the average number molecular mass Mₙ.

R¹ is selected from unsaturated groups, comprising C═C-group-containing groups (alkenyl groups), e.g.: n-, iso-, tertiary or cyclic alkenyl, C₆-C₃₀-cycloalkenyl, C₈-C₃₀-alkenylaryl, cycloalkenylalkyl, vinyl, allyl, methallyl, 3-butenyl, 5-hexenyl, 7-octenyl, ethyliden-norbornyl, styryl, vinylphenylethyl, norbornenyl-ethyl, limo-nenyl, optionally substituted by one or more O- or F-atoms, or C≡C-group-containing groups (alkinyl groups), optionally comprising one or more O- or F-atoms.

The alkenyl radicals are preferable attached to terminal silicon atoms, the olefin function is at the end of the alkenyl group of the higher alkenyl radicals, because of the more ready availability of the alpha-, omega-dienes used to prepare the alkenylsiloxanes.

Preferred groups for R¹ are vinyl, 5-hexenyl, cyclohexenyl, limonyl, styryl, vinylphenylethyl.

Z includes for example divalent aliphatic or aromatic n-, iso-, tertiary-or cyclo-alkylene with up to 14 carbon atoms, arylene or alkylenearyl groups.

Z forms bridging elements between two siloxy units.

The content of the Z groups does not exceed 30 mol. % preferably not exceed 20 mol. % of all siloxy units. Preferably Z is absent.

Preferred examples of suitable divalent hydrocarbon groups Z include any alkylene residue, preferably such as —CH₂—, —CH₂CH₂—, —CH₂(CH₃)CH—, —(CH₂)₄—, —CH₂CH(CH₃)CH₂—,—(CH₂)₆—, —(CH₂)— and —(CH₂)₁₈—; cycloalkylene radical, such as cyclohexylene; arylene radicals, such as phenylene, xylene and combinations of hydrocarbon radicals, such as benzylene, i.e. —CH₂CH₂—C₆H₄—CH₂CH₂—, —C₆H₄CH₂—. Preferred groups are alpha, omega-ethylene, alpha, omega-hexylene or 1,4-phenylene.

Further examples for the group Z include divalent halohydrocarbon radicals; e.g. any divalent hydrocarbon group wherein one or more hydrogen atoms have been replaced by halogen, such as fluorine, chlorine or bromine. Preferable divalent halohydrocarbon residues have the formula —CH₂CH₂(CF₂)₁₋₁₀CH₂CH₂— such as for example, —CH₂CH₂CF₂CF₂CH₂CH₂— or other examples of suitable divalent hydrocarbon ether radicals and halohydrocarbon ether radicals including —CH₂CH₂OCH₂CH₂—, —C₆H₄—O—C₆H₄—, —CH₂CH₂CF₂OCF₂CH₂CH₂—, and —CH₂CH₂OCH₂CH₂CH₂—.

In one embodiment, the irradiation-curable silicone composition according to the current invention comprises at least one linear polydiorganosiloxane A1), having at least one alkenyl group at the terminal siloxy groups thereof, and having no alkenyl groups at the non-terminal siloxy groups thereof.

According to another embodiment of the irradiation-curable silicone composition according to the current invention the component A1) is preferably at least one linear polydiorganosiloxane of the formula (Ia1),

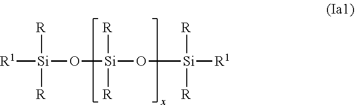

wherein each R is independently selected from saturated or aromatic organic groups, each R¹ is independently selected from alkenyl groups, and x is ≥0.

In one embodiment of the current invention, the variable x, which was introduced with regards to the structure (Ia1) above, is 10 to 2000, preferably 10 to 1000. These ranges are meant to comprise both end-points each. The variable x is an average value calculated either from the number-average molecular weight Mₙ of the polydiorganosiloxanes of the formula (Ia1), which is determined by gel permeation chromatography using polystyrene standard, or using ¹H NMR.

Further preferred structures of the alkenyl-terminated polydiorganosiloxane A1) include:

ViMe₂SiO(Me₂SiO)₁₀₋₂₀₀₀ SiMe₂ Vi (1a),

ViPhMeSiO(Me₂SiO)₁₀₋₂₀₀₀ SiMePhVi (1b),

ViMezSiO(Me₂SiO)₁₀₋₁₀₀₀SiMe₂ Vi (1c)

ViMe₂SiO(Me₂SiO)₁₀₋₂₀₀SiMe₂ Vi (1d).

wherein Vi is a vinyl group, Me is a methyl group and Ph is a phenyl group. Particularly preferred are linear polydiorganosiloxanes of formula (1a) with x ranging from 10 to 2000, more particularly preferred are the structures of the formula (1c) with x ranging from 10 to 1000. These ranges are meant to comprise both end points each.

Furthermore, the use of resinous polyorganosiloxanes of the following formula as component A1) is possible:

{[Q][R¹⁰O_{1/2}]ₙ[M]_{0,01-10}[T]_{0-50, preferably 0}[D]_{0-1000, preferably 0}}ₘ (Ia2)
wherein
Q, T, M, D are as defined above,
n=0 to 3, preferably n=0,
m is as defined above,
R¹⁰ is hydrogen, C₁-C₂₅-alkyl, such as methyl, ethyl, n-propyl, iso-propyl, n-, iso-and tert.-butyl, alkanoyl, such acyl, aryl, —N═CHR, such as butanonoxime, alkenyl, such as propenyl, with the proviso that there is at least one group selected from M*, D* and T *. Most preferred resinous polyorganosiloxanes applied as component A1) are of the formula consisting of Q and M* units, e.g:

{[Q][M*]_{0,01-10, preferably 1-10}}ₘ (Ia3)
wherein Q, M* and m are as defined above, and m is preferably 1 to 20.

One preferred embodiment of the compounds (Ia3) is provided by way of example by monomeric to polymeric compounds which can be described via the formula [(Me₂R¹SiO_{0.5})_{K}SiO_{4/2}]₁₋₁₀₀₀ wherein index k is from 0.3 to 4. Such resinous molecules can contain significant concentrations of SiOH— and/or (C₁-C₆)-alkoxy-Si groups of up to 10 mol. % related to the silicon atoms.

Particular preferred resinous polyorganosiloxanes A1) include e.g.
Q(M*)₄,
M₂D₁₀₋₃₀T*₁₀₋₃₀,
M₂D*₁₀₋₃₀T₁₀₋₃₀ and
[M*₁₋₄Q]₁₋₄₀.

The component A1) preferably has a viscosity at 20° C. from 0.1 to 500 Pa·s (measured at a shear rate of D=10 s⁻¹).

The Si-alkenyl- or alkenyl content of the alkenyl terminated polydiorganosiloxanes A1) with formula Ia1) is preferably at least 0.0075 mmol/g, and at most preferably 0.8 mmol/g, more preferably at least 0.01 mmol/g, and at most preferably 0.7 mmol/g, even more preferably at least 0.010 mmol/g, and at most preferably 0.5 mmol/g (millimoles alkenyl bonded to Si per gram of A1).

The alkenyl content of the component A1) can be determined here by way of ¹H NMR—see A. L. Smith (ed.): The Analytical Chemistry of Silicones, J. Wiley & Sons 1991 Vol. 112 pp. 356 et seq. in Chemical Analysis ed. by J. D. Winefordner.

The component A1) can be used as a single component of one Si-alkenyl-containing polysiloxane or as mixtures of at least two thereof.

In one embodiment of the current invention the irradiation-curable silicone composition comprises at least 50 weight-%, preferably at least 60 weight-%, more preferably at least 65 weight-% of the component A1) based on the total amount of the composition.

In one embodiment of the current invention the irradiation-curable silicone composition comprises less than 95 weight-%, preferably less than 90 weight-%, more preferably less than 85 weight-% of the component A1) based on the total amount of the composition.

In one embodiment the component A1) comprises at least one polydiorganosiloxane A11) having a viscosity at 20° C. and a shear rate D of 10 s⁻¹ of 5 to 300 Pa·s, preferably of 10 to 200 Pa·s, more preferably 20 to 150 Pa·s.

In one embodiment of the current invention, the variable x, which was introduced with regards to the structure (Ia1) above, is 200 to 2000, preferably 500 to 1200 for component A11). These ranges are meant to comprise both end-points each.

The Si-alkenyl- or alkenyl content of the alkenyl terminated polydiorganosiloxanes A11) with formula Ia1) is preferably at least 0.0075 mmol/g, and at most preferably 0.075 mmol/g, more preferably at least 0.01 mmol/g, and at most preferably 0.05 mmol/g, even more preferably at least 0.010 mmol/g, and at most preferably 0.04 mmol/g (millimoles alkenyl bonded to Si per gram of A11).

In one embodiment of the current invention the irradiation-curable silicone composition comprises at least 50 weight-%, preferably at least 55 weight-%, more preferably at least 60 weight-% of the component A11), based on the total amount of the composition.

In one embodiment of the current invention the irradiation-curable silicone composition comprises less than 95 weight-%, preferably less than 90 weight-%, more preferably less than 85 weight-% of the component A11) based on the total amount of the composition.

In another embodiment of the current invention, component A1) comprises at least one polydiorganosiloxane A12) having a viscosity at 20° C. and at a shear rate of 10 s⁻¹ of less than 5 Pa·s, preferably of 0.1 to 3 Pa·s, more preferably 0.2 to 2 Pa·s.

The Si-alkenyl- or alkenyl content of the alkenyl terminated polydiorganosiloxanes A12) with formula Ia1) is preferably at least 0.1 mmol/g, and at most preferably 0.8 mmol/g, more preferably at least 0.125 mmol/g, and at most preferably 0.6 mmol/g, even more preferably at least 0.15 mmol/g, and at most preferably 0.5 mmol/g (millimoles alkenyl bonded to Si per gram of A12).

In one embodiment of the current invention the irradiation-curable silicone composition comprises ≥0 to less than 5 weight-%, preferably less than 3 weight-%, more preferably less than 2 weight-% of the component A12), based on the total amount of the composition.

In a preferred embodiment component A1) comprises a combination of at least one polydiorganosiloxane A11) and at least one polydiorganosiloxane A12), wherein the polydiorganosiloxanes A11) and A12) are as defined above.

### Component A2

The irradiation-curable silicone composition according to the current invention comprises at least one linear polydiorganosiloxane A2), having a complex viscosity of at least 1000 Pa·s measured in the oscillation mode at 20° C. and being selected form the group of:
a linear polydiorganosiloxane with no functional alkenyl group A2-1) and
a linear polydiorganosiloxane with at least one alkenyl group bound to a silicon atom A2-2)

The complex viscosity is defined as above.

The complex viscosity of A2) is at least 1000 Pa·s at 20° C., preferably at least 2500 Pa·s at 20° C. and more preferably at least 5000 Pa·s at 20° C. in the oscillation mode as described above.

In one embodiment of the current invention the complex viscosity of A2) is less than or equal to 25000 Pa·s at 20° C., preferably less than or equal to 15000 Pa·s at 20° C. and more preferably less than or equal to 10000 Pa·s at 20° C. in the oscillation mode as described above.

According to one embodiment of the irradiation-curable silicone composition according to the current invention, the component A2) is at least one polydiorganosiloxane of the formula (Ib),

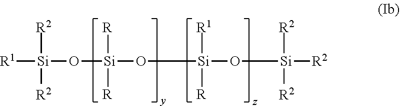

wherein R and R¹ are as defined above; R² is selected from R or R¹, and y is ≥0, and z≥0, and the sum of y+z is such that the complex viscosity as defined above and measured at 20° C. is at least 1000 Pa·s, preferably at least 2500 Pa·s and more preferably at least 5000 Pa·s in the oscillation mode as described above.

In one embodiment the complex viscosity of the compound according to formula (Ib) at 20° C. as described above is less than or equal to 25000 Pa·s at 20° C., preferably less than or equal to 15000 Pa·s at 20° C. and more preferably less than 10000 Pa·s at 20° C. in the oscillation mode as described above.

In one embodiment of the current invention, the variable y, which was introduced with regards to the structure (Ib) above, is 2000 to 10000, preferably 3000 to 8000. These ranges are meant to comprise both end-points each. The variable y is an average value calculated either from the number-average molecular weight Mₙ of the polydiorganosiloxanes of the formula (Ib), which is determined by gel permeation chromatography using polystyrene standard, or using ¹H NMR.

In one embodiment of the current invention, the variable z, which was introduced with regards to the structure (Ib) above is 0 to 350, preferably 0 to 250, more preferably 0 to 50.

These ranges are meant to comprise both end-points each. The variable z is an average value calculated either from the number-average molecular weight Mₙ of the polydiorganosiloxanes of the formula (Ib), which is determined by gel permeation chromatography using polystyrene standard, or using ¹H NMR.

In one embodiment of the irradiation-curable silicone composition according to the current invention component A2) is component A2-1). Component A2-1) is a linear polydiorganosiloxane of formula (Ib) where R²═R and z=0. Preferably, in said Component A2-1) R² and R are methyl and y is preferably 3000 to 8000.

In another embodiment of the irradiation-curable silicone composition according to the current invention component A2) is component A2-2). Component A2-2) is a linear polydiorganosiloxane of formula (Ib) wherein at least one, preferably one R² on each terminal siloxy group is R¹; i.e. the at least one, preferably one R² on each terminal siloxy group is selected from alkenyl groups.

In this component A2-2) the at least one R²═R¹ is preferably a vinyl group, and y is preferably 3000 to 8000, R is preferably methyl and z=0.

In one embodiment of the current invention the alkenyl-content in compound A2-2) of formula (Ib) is at least 0.002 mmol/g, and at most 5 mmol/g, more preferably at least 0.0025 mmol/g, and at most preferably 3 mmol/g, even more preferably at least 0.004 mmol/g, and at most preferably 2 mmol/g. These values refer to the amount of alkenyl groups (in mmol) within the compound A2-2) per mass (in gram) of said compound A2-2). Preferably the alkenyl group in compound A2-2) is a vinyl group.

In another embodiment of the irradiation-curable silicone composition according to the current invention, component A2) is component A2-2) a linear polydiorganosiloxane of formula (Ib) wherein at least one, preferably one R² on each terminal siloxy group is R¹; i.e. the at least one, preferably one R² on each terminal siloxy group is selected from alkenyl groups and y is 3000 to 8000 and z≥1. In this component A2-2) the at least one R²═R¹ is preferably a vinyl group, y is preferably 3000 to 8000 and z is preferably 1 to 250, more preferably 0 to 50.

In one embodiment according to the invention the irradiation-curable silicone according to the current invention, component A2) is component A2-2) a linear polydiorganosiloxane of formula (Ib) wherein one R² on each terminal siloxy group is R¹=vinyl, R is methyl, y is preferably 3000 to 8000 and z is preferably 1 to 250, more preferably 0 to 50.

In a further embodiment of the irradiation-curable silicone composition according to the current invention, component A2) is component A2-2) a linear polydiorganosiloxane of formula (Ib) wherein each R² on each terminal siloxy group is R; R being independently selected from alkyl groups, preferably R²═R is methyl, y is preferably 3000 to 8000 and z≥1.

In a further preferred embodiment of the irradiation-curable silicone composition according to the current invention, component A2) is component A2-2) a linear polydiorganosiloxane of formula (Ib) wherein R² on each terminal siloxy group is R; R being independently selected from alkyl groups, preferably R²═R is methyl, y is 3000 to 8000 and z is preferably 1 to 250, more preferably 0 to 50.

In one embodiment of the irradiation-curable silicone composition according to the current invention component A2) is A2-2), a linear polydiorganosiloxane of formula (Ib) wherein at least one alkenyl group is bound to a silicon atom and this compound has a complex viscosity of at least 1000 Pa·s and an Si-alkenyl- or alkenyl content which is preferably at least 0.002 mmol/g, and at most preferably 5 mmol/g, more preferably at least 0.0025 mmol/g, and at most preferably 3 mmol/g, even more preferably at least 0.004 mmol/g, and at most preferably 2 mmol/g (millimoles alkenyl bonded to Si per gram of A2-2).

In a preferred embodiment of the invention component A2) has a complex viscosity at 20° C. of at least 1000 Pa·s, more preferably the viscosity is in the range of 2500 to 25000 Pa·s and even more preferably in the range of 5000 to 15000 Pa·s.

In a further embodiment according to the invention, in the case A2) is a mixture of A2-1) and A2-2) then the complex viscosity is the complex viscosity of the said mixture.

In one embodiment of the current invention the irradiation-curable silicone composition comprises at least 5 weight-%, preferably at least 8 weight-%, more preferably more than 10 weight-%, more preferably at least 12 weight-%, still more preferably at least 15 weight-% of the component A2), based on the total amount of the composition.

In one embodiment of the current invention the irradiation-curable silicone composition comprises up to 50 weight-%, preferably up to 40 weight-%, more preferably up to 35 weight-%, still more preferably up to 30 weight-% of the component A2), based on the total amount of the composition.

### Component B

The irradiation-curable silicone composition according to the current invention comprises at least one polyorganohydrogensiloxane having at least one SiH group, preferably two SiH groups (component B)).

In one embodiment of the invention the component B) is selected from one or more polyorganohydrogensiloxanes of the general formula (IIa):

[M¹ₐ₁D¹_{b1}T¹_{c1}Q¹_{d1}Zₑ₁]ₘ₁ (IIa)
wherein:
M¹=R₃SiO_{1/2}, and/or M**
D¹=R₂SiO_{2/2}, and/or D**
T¹=RSiO_{3/2}, and/or T**
Q¹=SiO_{4/2},
with M**=HR₂SiO_{1/2}, D**=HRSiO_{2/2}, T**=HSiO_{3/2},
Z is as defined above, and
R is as defined above,
a1 is 0.01-10, preferably a1 is 2-5, more preferably a1 is 2;
b1 is 0-1000, preferably b1 is 10-500;
c1 is 0-50, preferably c1 is 0;
d1 is 0-5, preferably d1 is 0;
e1 is 0-3, preferably e1 is 0;
m1 is 1-1000, preferably m1 is 1-500, more preferably m1 is 1,
with the proviso that there is at least one group selected from M**, D** or T**.

Preferably, the component B) is selected from polyorganohydrogensiloxanes (or SiH-containing polysiloxane) that have only hydrocarbyl groups, more preferably alkyl and aryl groups, even more preferably only methyl or phenyl groups, and most preferably only methyl groups as organic residues R as defined above.

Preferably, the SiH-containing polysiloxane B) have at least 10, preferably at least 15, more preferably at least 20, still more preferably at least 25 and most preferably at least 30 silicon atoms.

The range for M¹-, D¹-, T¹-and Q¹-units present in the molecule can cover nearly all values representing liquid and solid resins. Optionally these siloxanes can comprise additional traces of C₁-C₆-alkoxy or Si-hydroxy groups remaining from the synthesis.

Furthermore, the use of resinous polyorganohydrogensiloxanes of the following formula as component B) is possible:

{[Q¹][R¹⁰O_{1/2}]ₙ₁[M¹]_{0,01-10}[T¹]_{0-50, preferably 0}[D¹]_{0-1000, preferably 0}}ₘ₁ (IIb)
wherein
Q¹, T¹, M¹, D¹ are as defined above,
n1=0 to 3, preferably n1 =0,
m1 is as defined above,
R¹⁰ is hydrogen, C₁-C₂₅-alkyl, such as methyl, ethyl, n-propyl, iso-propyl, n-, iso-and tert.-butyl, alkanoyl, such acyl, aryl, —N═CHR, such as butanonoxime, alkenyl, such as propenyl,
   with the proviso that there is at least one group selected from M**, D** and T**. Most preferred resinous polyorganohydrogensiloxanes applied as component B) are of the formula consisting of Q¹ and M** units, e.g.

{[Q¹][M**]_{0,01-10, preferably 1-10}}ₘ₁ (IIc)

wherein Q¹, M** and m1 are as defined above, and m1 is preferably 1 to 20, more preferably m1=1.

One preferred embodiment of the compounds (IIc) is provided by way of example by monomeric to polymeric compounds which can be described via the formula [(Me₂HSiO_{0.5})ₖSiO_{4/2}]₁₋₁₀₀₀ wherein index k is from 0.3 to 4. Such resinous molecules can contain significant concentrations of SiOH— and/or (C₁-C₆)-alkoxy-Si groups of up to 10 mol. % related to the silicon atoms.

Particularly preferred resinous polyorganohydrogensiloxanes B) include e.g.
Q¹(M**)₄,
M¹₂D¹₁₀₋₃₀T**₁₀₋₃₀,
M¹₂D**₁₀₋₃₀T¹₁₀₋₃₀, and
[M**₁₋₄Q¹]₁₋₄₀.

The component B) preferably has a viscosity from 2 to 2000 mPa·s, preferably from 1 to 1000 mPa·s, still more preferably 2 to 100 mPa·s (measured at 20° C. and a shear rate of D=10 s⁻¹).

The SiH-content of the polyorganohydrogensiloxanes B) is preferably at least 0.1 mmol/g, more preferably at least 0.2 mmol/g, and at most preferably 20 mmol/g, more preferably at most 18 mmol/g, even more preferably 0.1 to 17 mmol/g, and most preferably 0.2 to 16 mmol/g (millimoles SiH per gram of component B))

The component B) can be used as a single component of one SiH-containing polysiloxane or as mixtures of at least two thereof.

If an increase of the cure rate is required, it is preferred to use some organopolysiloxanes B) having HMe₂SiO_{0.5}— units or homo MeHSiO-polymers to adjust the cure rate to shorter times.

If it is necessary to still further increase the cure rate, this can be achieved by way of example via an increase of the molar ratio of SiH to Si-alkenyl, or an increased amount of catalyst C).

In another embodiment of the current invention, the component B) is selected from linear polyorganohydrogensiloxanes, preferably having SiH groups in the non-terminal siloxy units thereof, such as

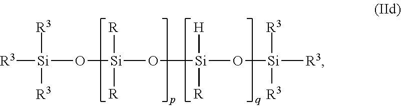

wherein R is as defined above, and R³ is selected from R and H, and p≥0 and q≥1.

In one of the embodiments, the component B) of formula (IId) has at least 1, more preferably at least 3, in some instances also more than 15 and more than 18 SiH-groups per molecule.

In one embodiment, the component B) can be used as a mixture of at least one SiH-containing polysiloxane of formula (IIc) and at least one SiH-containing polysiloxane of formula (IId).

### Component C

The irradiation-curable silicone composition according to the current invention comprises at least one irradiation-activatable catalyst (component C))

The catalyst component C) for the hydrosilylation reaction of the inventive composition is a compound, which facilitates the reaction of the silicon-bonded hydrogen atoms of component B) with the silicon-bonded olefinic hydrocarbon substituents of component A). The metal or organo metal compound is generally based on a platinum group metal. Without wishing to be bound by theory, it is believed that the catalyst C) includes complexes with sigma-and pi-bonded carbon ligands as well as ligands with S—, N, or P atoms, metal colloids or salts of the afore mentioned metals. The catalyst can be present on a carrier such as silica gel or powdered charcoal, bearing the metal, or a compound or complex of that metal. Preferably, the metal of component C) is any platinum complex compound.

A typical platinum containing catalyst component in the polyorganosiloxane compositions of this invention is any form of platinum (0), (II) or (IV) compounds, which are able to form complexes.

The amount of platinum-containing catalyst component that is used in the compositions of this invention is not narrowly limited as long as there is a sufficient amount to accelerate the hydrosilylation between A) and B) at the desired temperature in the required time in the presence of all other ingredients of the inventive composition. The exact necessary amount of said catalyst component will depend upon the particular catalyst, the amount of other inhibiting compounds and the SiH to olefin (bound to Si) ratio and is not easily predictable. However, for platinum catalysts said amount can be as low as possible due to cost reasons. Preferably, one should add more than one part by weight of platinum for every one million parts by weight of the organosiloxane components A1) and B) to ensure curing in the presence of other undefined inhibiting traces. For the compositions of this invention, the amount of platinum containing catalyst component to be applied is preferably sufficient to provide from 1 to 400 ppm preferably 2 to 200 ppm, more preferred 4 to 100 ppm by weight platinum per weight of polyorganosiloxane components A) plus B). According to one embodiment said amount is at most 20 ppm, more preferably at most 10 ppm and, more preferred at most 8 ppm.

Component C) is preferably selected from the group of organo metal compounds, salts or metals, having the ability to catalyze hydrosilylation wherein the metal is selected from the group of Ni, Ir, Rh, Ru, Os, Pd and Pt compounds as taught in U.S. Pat. Nos. 3,159,601; 3,159,662; 3,419,593; 3,715,334; 3,775,452 and 3,814,730.

Preferably the transition metal catalyst C) is selected from hydrosilylation catalysts comprising at least one metal selected from the group consisting of platinum, rhodium, palladium, ruthenium and iridium, preferably platinum.

Catalyst capable of being photo-activatable is preferably selected among organometallic compounds, i.e. comprise carbon-containing ligands, or salts thereof. In a preferred embodiment photoactive catalyst C) has metal carbon bonds, including sigma-and pi-bonds. Preferably the catalyst capable of being photo-activated C) is an organometallic complex compound having at least one metal carbon sigma bond, still more preferably a platinum complex compound having preferably one or more sigma-bonded alkyl and/or aryl group, preferably alkyl group(s). Sigma-bonded ligands include in particular, sigma-bonded organic groups, preferably sigma-bonded C1-C6-alkyl, more preferably sigma-bonded methyl groups, sigma-bonded aryl groups, like phenyl, Si and O substituted sigma bonded alkyl or aryl groups, such as trisorganosilylalkyl groups, sigma-bonded bonded silyl groups, like trialkyl silyl groups. Most preferred photo-activatable catalysts include η⁵— (optionally substituted)—cyclopentadienyl platinum complex compounds having sigma-bonded ligands, preferably sigma-bonded alkyl ligands.

Examples of catalysts capable of being photo-activated include n-diolefin-sigma-aryl-platinum complexes, such as disclosed in U.S. Pat. No. 4,530,879, EP 122008, EP 146307 (corresponding to U.S. Pat. No. 4,510,094 and the prior art documents cited therein), or US 2003/0199603, and also platinum compounds whose reactivity can be controlled by way for example using azodicarboxylic esters, as disclosed in U.S. Pat. No. 4,640,939 or diketonates.

Platinum compounds capable of being photo-activated that can be used are moreover those selected from the group having ligands selected from diketones, e.g. benzoylacetones or acetylenedicarboxylic esters, and platinum catalysts embedded into photo-degradable organic resins. Other Pt-catalysts are mentioned by way of example in U.S. Pat. No. 3,715,334 or U.S. Pat. No. 3,419,593, EP 1 672 031 A1 and Lewis, Colborn, Grade, Bryant, Sumpter, and Scott in Organometallics, 1995, 14, 2202-2213, all incorporated by reference here.

Catalysts capable of being photo-activated can also be formed in-situ in the silicone composition to be shaped, by using Pt(0)-olefin complexes and adding appropriate photo-activatable ligands thereto.

The catalysts capable of being photo-activated that can be used here are, however, not restricted to these above-mentioned examples.

In one embodiment of the current invention the irradiation-activatable catalyst C) is selected from organometallic platinum compounds, preferably from optionally substituted cyclopentadienyl platinum compounds, preferably from (η5-cyclopentadienyl)-trimethyl-platinum and (η⁵-cyclopentadienyl)-triphenyl-platinum complexes, is most preferably component C) is (methylcyclopentadienyl)-trimethyl platinum(IV).

The catalyst capable of being photoactivated can be used as such or supported on a carrier.

### Component D

Optionally the irradiation-curable silicone composition according to the current invention comprises one or more auxiliary components (component D)).

In one embodiment of the current invention the irradiation-curable silicone composition comprises less than 3 weight-% of an adhesion promoter, preferably less than 1 weight-% of an adhesion promoter, more preferably 0 to 0.1 weight-% of an adhesion promoter.

The curable polyorganosiloxane composition optionally comprises at least one adhesion promoter (D) as defined in the following excerpt of U.S. Pat. No. 9,991,406.
“Component (D) is preferably selected from at least one of
(D1): at least one organosiloxane, comprising at least one alkoxy silyl group,
(D2): at least one organosilane, comprising at least one alkoxy silyl group,
(D3): at least one aromatic organic compound having at least two aromatic moieties and at least one group reactive in hydrosilylation.
Component (D1) is preferably an polyorganosiloxane comprising at least one unit selected from the group consisting of
RHSiO_{2/2} and
R⁵(R)SiO_{2/2},
wherein R is as defined above and may be identical or different, R⁵ is selected from the group consisting of unsaturated aliphatic group with up to 14 carbon atoms, epoxy-group-containing aliphatic group with up to 14 carbon atoms, cyanurate-containing group, and an isocyanurate-containing group, and
further comprising at least one unit of the formula (3):

—O_{2/2}(R)Si—R⁴—SiR_{d}(OR³)_{3-d} (3)
wherein
R is as defined above and may be identical or different,
R³ is selected from H (hydrogen) and alkyl radicals having 1 to 6 carbon atoms, and may be identical or different,
R⁴ is a difunctional optionally substituted hydrocarbyl radical with up to 15 carbon atoms, which may contain one or more heteroatoms selected from O, N and S atoms, and which is bond to the silicon atoms via an Si—C-bond, and
d is 0 to 2.
Examples of component (D1) include compounds of the formulas (3a-3d):

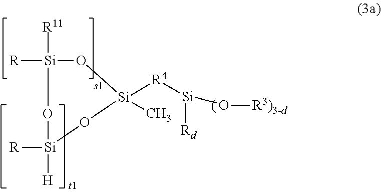

R¹¹ is R or R⁵, wherein R, R³, R⁴ and R⁵ are as defined above and may be identical or different,
S1=0-6, preferably 1
t1=0-6, preferably 1 or 2
S1+t1 =2-6, preferably 2 or 3
with the proviso that there is at least one group —(OSi(R)H)— or —(OSi(R)(R¹¹)— in the compound, preferably a compound of the formula:

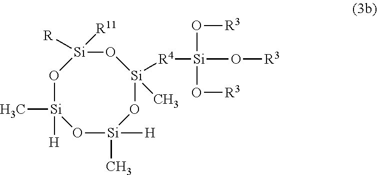

wherein R, R³, R⁴ and R¹¹ are as defined before, and ring positions isomers thereof, a compound of the formula:

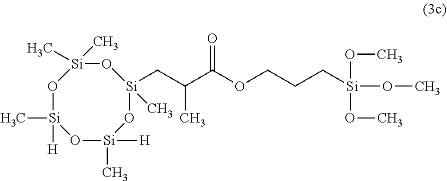

and ring positions isomers thereof, a compound of the formula.
Furthermore compounds of formula:

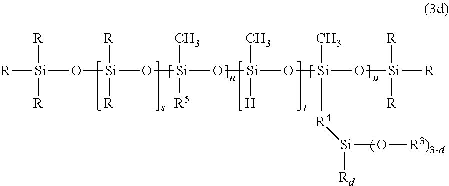

wherein:
R, R³, R⁴, R⁵ are as defined above,
s=0-10 preferably =0-5
t=0-50 preferably =2-30
u=1-10 preferably =1
s+t+u=≤70
with the proviso that there is at least one group —(OSi(R)H)— or —(OSi(R)(R⁵)— in the compound. These compounds may comprise to a certain content Q or T branching groups, replacing the D units.
R⁵ is for example selected from:

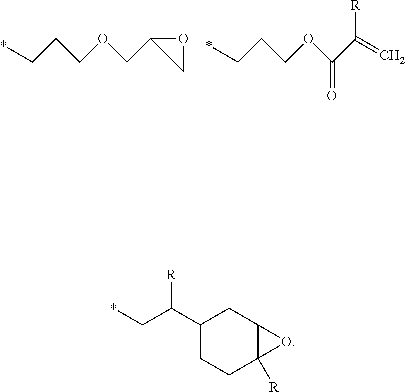

Component (D2) is preferably selected from compounds of the formula (4):

X—(CR⁶₂)e-Y—(CH₂)ₑSiR_{d}(OR³)_{3-d}
wherein
X is selected from the group consisting of halogen, pseudohalogen, unsaturated aliphatic group with up to 14 carbon atoms, epoxy-group-containing aliphatic group with up to 14 carbon atoms, cyanurate-containing group, and an isocyanurate-containing group, Y is selected from the group consisting of a single bond, a heteroatomic group selected from —COO—, —O—, —S—, —CONH—, —HN—CO—NH—,
R⁶ is selected from hydrogen and R as defined above,
e is 0, 1, 2, 3, 4, 5, 6, 7, or 8, and may be identical or different,
R is as defined above and may be identical or different,
R³ is as defined above and may be identical or different,
d is 0, 1, or 2.
Preferred examples of component (D2) include:

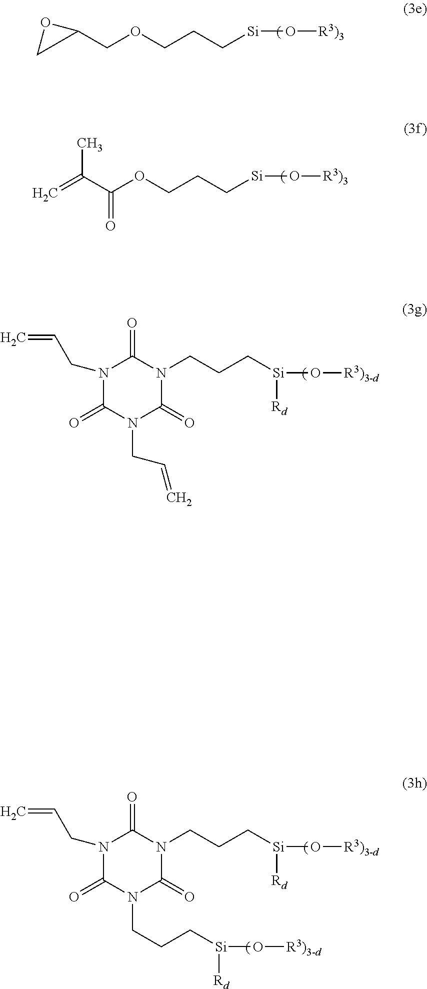

wherein R and d are as defined above.
Component (D2) apart from acting as an adhesion promoter, can serve in addition as in-situ surface treating agent for filler (E). It is preferred to use mixtures of silanes of the component (D2) to obtain acceptable adhesion properties at reduced costs.
Component (D3) is preferably selected from compounds of the formula (3i):

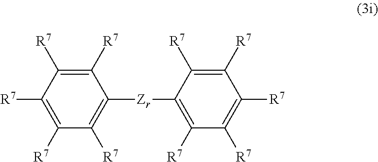

wherein
r is 0 or 1,
R⁷ may be the same or different group, which is selected from the group consisting of a hydrogen atom, a hydroxyl group, a halogen atom, an alkyl group, alkenyl group, alkoxy group, alkenyloxy group, alkenylcarbonyloxy group and an aryl group, and a group of formula -E_{f}-Si(OR)_{3-d}R_{d}, wherein R is identical or different, and d is as defined above,
a group of formula —O-Si(R)₂R₁, wherein R and R₁ are as defined above,
a group of formula -E_{f}-Si(R)₂H, wherein R is as defined above,
wherein E is a divalent organic group with up to 8 carbon atoms and 0 to 3 hetero atomic groups selected from —O—, —NH—, C═O, and —C(═O)O—, and
f is 0 or 1,
and Z is selected from the following groups:

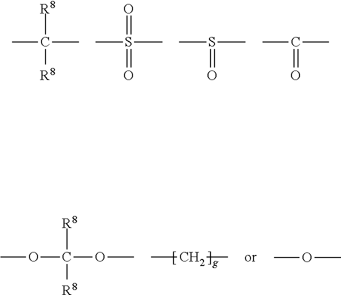

wherein R⁸ is selected from the group of a hydrogen atom, a halogen atom, or a substituted or unsubstituted alkyl group, aryl group, alkenyl group and alkynyl group, and g is a positive number of at least 2,
wherein at least one of the groups selected from R⁷ and R⁸ is reactive in hydrosilylation.
Preferred components (D3) include:

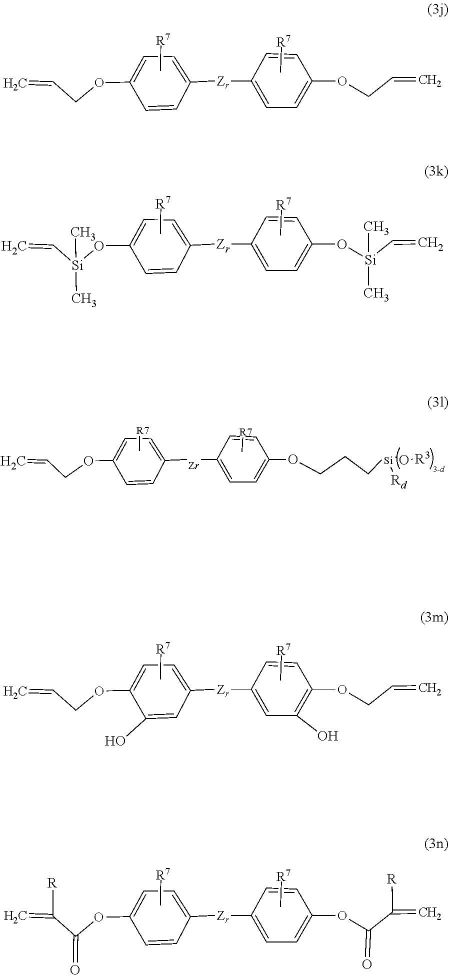

wherein Zr, R⁷, R³, R and d are each as defined above.”

### Component D4

The curable polyorganosiloxane compositions according to the invention may comprise one or more, if appropriate surface-modified, reinforcing filler. Reinforcing fillers are characterized by a BET surface area of 50 m²/g or more.

In general, if curable polyorganosiloxane compositions are irradiation-cured such fillers should be transparent and allow or high light-transmittance.

The fillers include by way of example all of the fine-particle fillers, i.e. those having particles smaller than 100 μm, i.e. preferably composed of such particles. These can be mineral fillers, such as silicates, carbonates, nitrides, oxides, or silicas. The fillers are preferably those known as reinforcing silicas, which permit production of elastomers having sufficient transparency for irradiation. Preferred are reinforcing silicas which improve properties of the cured encapsulants after crosslinking, in particular those increasing the strength. Examples are fumed or precipitated silicas whose BET surface areas are from 50 to 400 m²/g. Preferably these fillers are surface-hydrophobicized. If component D4) is used, its amounts are from 1 to 100 parts by weight, preferably from 0 to 70 parts by weight, even more preferably from 0 to 50 parts by weight, even more preferably from 5 to 45 parts by weight based on 100 parts by weight of components A) and B).

Fillers whose BET surface areas are above 50 m2/g permit production of silicone elastomers with improved properties. In view of strength and transparency fumed silicas are preferred, and even more preferred silicas are, for example, Aerosil® 200, 300, HDK® N20 or T30, Cab-O-Sil® MS7 or HS5 having more than 200 m2/g BET surface area. As BET surface area rises, the transparency of the silicone mixtures in which these materials are present also rises. Examples of trade names of the materials known as precipitated silicas, or wet silicas, are Vulkasil@VN3, or FK 160 from Evonik (formerly Degussa), or Nipsil®LP from Nippon Silica K.K. and others.

It is preferred to use silica fillers having BET-surface areas of 50 m²/g or more, preferably having a BET-surface of at least 150 m²/g. Such compositions can be photo-activated if desired due to sufficient transparency.

The fillers D4) may be subject of any suitable conventional surface-treatment with suitable surface-treatment agents belonging to hydrophobizing treatment with a suitable hydrophobizing agent, dispersing treatment with suitable dispersing agents which influence the interaction of the filler with the silicone polymer, e.g. influence thickening action. The surface treatment of the fillers is preferably a hydrophobation with silanes or with siloxanes. It can by way of example take place in situ via addition of silazanes, such as hexamethyldisilazane and/or 1,3-divinyltetramethyldisilazane, with addition of water, and ‘in-situ’-hydrophobation is preferred. It can also take place with other familiar filler-treatment agents with polyorganosiloxanediols whose chain lengths are from 2 to 50 and which bear unsaturated organic radicals, with the aim of providing reactive sites for the crosslinking reaction.

Examples of commercially available silicas pre-hydrophobized with various silanes are: Aerosil® R 972, R 974, R 976, or R 812, or, for example, HDK® 2000 or H30 Examples of trade names for materials known as hydrophobized precipitated silicas or wet silicas are e.g. Sipernat® D10 or D15 from Evonik (formerly Degussa).

Rheological properties, i.e. technical processing properties, of the non-cured silicone rubber mixtures can be influenced by the selection the amount of the type of the filler, its amount, and the nature of hydrophobization.

Other filler could be selected from TiO_{2,} nano-TiO_{2,} optical lightener (like Tinopal OB) and nano-silica.

Silicon dioxide nanoparticles are also known as silica nanoparticles or nano-silica, which have stability, low toxicity and an ability to be functionalized with a range of molecules and polymers. Nano-silica particles are divided into P-type and S-type according to their structure. The P-type particles are characterized by numerous nanopores, which have a pore rate of 0.61 ml/g and exhibit a higher ultraviolet reflectivity compared to the S-type; the latter also has a comparatively smaller surface area. When the filler is nano-silica and is included into the silicone composition according to the invention, then the cured silicone composition will be transparent for a good UV curing.

In one embodiment of the current invention the irradiation-curable silicone composition comprises less than 10 weight-% of a reinforcing filler, preferably less than 3% of a reinforcing filler, more preferably no filler.

### Non Reinforcement Filler D5)

Examples of materials serving as fillers or extenders (BET-surface areas <50 m²/g) are known as non-reinforcing fillers. They include for example powdered quartz, diatomaceous earths, powdered crystoballites, micas, aluminum oxides, and aluminum hydroxides. Titanium dioxides or iron oxides, Zn oxides, chalks, or carbon blacks whose BET surface areas are from 0.2 to less than 50 m2/g can be used also as heat stabilizer. These fillers are available under variety of trade names, examples being Sicron®, Min-U-Sil@, Dicalite®, Crystallite®. The materials known as inert fillers or extenders with BET surface areas below 50 m2/g should advantageously comprise no particles (<0.005% by weight) above 100 um for use in silicone rubbers, in order that further processing generates no problems during downstream processing, e.g. passage through sieves or nozzles, or the mechanical properties of the articles produced therefrom are adversely affected.

Among the opacifying fillers are also in particular non-transparent, in particular inorganic, pigments or carbon black.

The use of these opacifying fillers is preferred only when pigmentation is necessary or the physical function like thermal or electrical conductivity is a requirement.

The use of opaque non-transparent fillers requires changing the usual sequence of the activation and shaping steps in the process. Normally, if no or transparent fillers are used, the photo-activation through irradiation is carried out after the final shaping process. If opaque non-transparent fillers, which would inhibit the photo-activation of the photo-activatable catalyst, are used, the photo-activation step is carried out before the opaque non-transparent fillers are incorporated and the mixture is shaped.

### Ratios Between Different Components

In one embodiment of the current invention the irradiation-curable silicone composition comprises, based on 100 parts by weight of the total of A1) and A2), 50 to 95 parts by weight of A1) and 5 to 50 parts by weight of A2), preferably 60 to 90 parts by weight of A1) and 10 to 40 parts by weight of A2), more preferably 65 to 85 parts by weight of A1) and 15 to 30 parts by weight of A2).

In one embodiment of the current invention the irradiation-curable silicone composition comprises, based on 100 parts by weight of the total of A11) and A2-2), 50 to 95 parts by weight of A11) and 5 to 50 parts by weight of A2-2), preferably 60 to 90 parts by weight of A11) and 10 to 40 parts by weight of A2), more preferably 65 to 85 parts by weight of A11) and 15 to 30 parts by weight of A2).

In one embodiment of the current invention the irradiation-curable silicone composition comprises based on 100 parts by weight of the total of A11) and A2):
0 to 5 parts by weight of the component A12),
0.01 to 20 parts by weight of component B),
1 to 100 ppm of component C), and
0 to 10 parts by weight of component D).

### Properties of the Curable Silicone Composition of the Current Invention

In one embodiment of the current invention the irradiation-curable silicone composition has a viscosity of at least 150 Pa·s, preferably at least 175 Pa·s, more preferably at least 200 Pa·s at a shear rate D of 10 s⁻¹ and 20° C.

The viscosity was measured using plate/plate rheology method.

In one embodiment of the current invention the irradiation-curable silicone composition has a viscosity of at most 700 Pa·s at a shear rate D of 10 s⁻¹ and at 20° C.

In one embodiment of the current invention the irradiation-curable silicone composition has a viscosity of at least 150 Pa·s, preferably at least 175 Pa·s, more preferably at least 200 Pa·s and at most 700 Pa s at a shear rate D of 10 s⁻¹ and at 20° C.

In a preferred embodiment the irradiation-curable silicone composition has a viscosity of 300 to 400 Pa·s at a shear rate D of 10 s⁻¹ and 20° C.

In one embodiment of the current invention the irradiation-curable silicone composition comprises less than 10 weight-% of a resinous polyorganosiloxane having at least one siloxy group selected from T and Q groups, preferably less than 1% of said resinous polyorganosiloxane, more preferably no said resinous polyorganosiloxane wherein T and Q groups are defined below:
M=R₃SiO_{1/2}, or M*
D=R₂SiO_{2/2}, or D*
T=RSiO_{3/2}, or T*
Q=SiO_{4/2}

In one embodiment the irradiation-curable silicone composition is a ready to use one component system.

The wavelength used to cure the curable silicone composition of the current invention is not narrowly limited as long as the wavelength is capable to cure the composition within a reasonable timescale. In one embodiment of the current invention the cured compositions are obtained by irradiation curing, preferably UV curing.

In another embodiment according to the invention, the wavelength used for curing is in the UV region, for example between 100 nm to 500 nm.

### Properties of the Curable Silicone Composition of the Current Invention After Curing

In one embodiment of the current invention the cured composition provides an aspect ratio of at least 0.5. The aspect ratio refers to the ratio of the height to the width of the UV cured composition. The width and the height are determined, for example, with a digital microscope of the company Keyence. Below this value of 0.5 for the aspect ratio of the irradiation cured silicone composition, some bubbles can evolve or some other liquid composition can flow down.

Preferably, the aspect ratio is at least 0.6, more preferably at least 0.65, and even more preferably at least 0.75.

In one embodiment of the current invention the irradiation-curable silicone composition has, after curing, a hardness which is defined in the range of soft measured with penetration up to 75×0.1 [mm] with a quarter cone to Shore 00 up to 70 (Penetration is measured in accordance to DIN ISO 2137 and Shore hardness 00 in accordance to ASTM D2240-02b).

In one embodiment of the current invention the irradiation-curable silicone composition has, after curing, a transparency ≥65%, preferably, a transparency ≥75%, more preferably a transparency ≥85%, and even more preferably a transparency ≥90%.

Transparency is measured in accordance to ASTM D1003 with a haze-gard-dual from the company Byk.

In one embodiment of the current invention the irradiation-curable silicone composition has, after curing, a Yellowness Index (YI)≤10, more preferably ≤5, more preferably ≤1.

The Yellowness Index (YI) is measured in accordance to ASTM E313 with a CM 3600D device of company Konika Minolta.

The irradiation-curable silicone composition of the current invention is used, for example, as dam and sealing material in displays applications (optical bonding).

The irradiation-curable silicone composition of the current invention is used, for example in displays.

The current invention also relates to displays comprising the cured silicone compositions.

### EXAMPLES

In order to evaluate which composition results in dam material with a desirable aspect ratio after curing the nine compositions depicted in the table below were prepared at room temperature (25° C.). Each composition was applied with a Nordson XYZ roboter through a 1.6 mm nozzle at a dispersing speed of 10 mm/s as a line on a substrate using a 30 cc syringe at 5.34 bar. Subsequently the compositions are cured using a Metal Halide Lamp Panacol UV H255 by applying an energy of 2 to 4 J/cm² to the silicone composition.

The meaning of the components mentioned in said table 1 below is as follows:
Component A11) is either a linear vinyl terminated dimethylpolysiloxane having a viscosity of 65 Pa·s at a shear rate of D=10 s⁻¹ at 20° C. or a linear vinyl terminated siloxane having a viscosity of 165 Pa·s.
Component A2-2a) is a linear vinyl terminated dimethyl-co-(methyl (vinyl) polysiloxane having a complex viscosity of 6000 Pa·s in the oscillation mode and at 20° C.
Component B) is a linear poly-dimethyl-co-methylhydrogen siloxane (SiH polysiloxane) crosslinker B) with a viscosity of 40 mPa·s at a shear rate of D=10 s⁻¹ at 20° C.
UV cat C1) consists of 500 ppm UV catalyst, i.e. (methylcyclopentadiene) trimethylplatinum or TMMCpPt (IV) in a vinyl terminated polydimethylsiloxane A11) with a viscosity of 10 Pa·s at a shear rate of D=10 s⁻¹ at 20° C.
UV cat premix C2) is 1g TMMCpPt (IV) in 99 g of a linear terminated vinyl polydimethylsiloxane A12) with a viscosity of 1 Pa·s at 20° C. and a shear rate of 10 s⁻¹.

The above ingredients were mixed to get the irradiation curable silicone compositions according to the invention in a ratio between the component A11) (vinyl terminated and with vinyl group in the chain as pending group) and the vinyl polydiorganosiloxane A2-2a) ranging from 86:13 to 60:35 led to the required viscosities for the application of dams for displays (above 180 Pa·s at a shear rate of 10 s⁻¹ and 20° C.) for expected flowability and an aspect ratio of the dam above 0.5 (Table 1).

TABLE 1

| | | | | | | | Comp. | | | | |
|---|---|---|---|---|---|---|---|---|---|---|---|
| Raw materials | viscosity | | Ex 1 | Ex 2 | Ex 3 | Ex 4 | Ex 5 | Ex 6 | Ex 7 | Ex8 | Ex 9 |
| Linear vinyl terminated | 165 | Pa · s | | | | | 99.2 | | | | |
| polydimethylsiloxane A11) | | | | | | | | | | | |
| Linear vinyl terminated | 65 | Pa · s | 75 | 70 | 65 | 74.2 | | 94.2 | 89.2 | 84.2 | 79.2 |
| polydimethylsiloxane A11) | | | | | | | | | | | |
| Linear vinyl | 6000* | Pa · s | 20 | 25 | 30 | 25.0 | | 5 | 10 | 15 | 20 |
| polydimethylsiloxane A2-2a) | | | | | | | | | | | |
| having 0.024 mmol | | | | | | | | | | | |
| Si-Vinyl(SiVi)/g | | | | | | | | | | | |
| Linear polydimethyl- | 40 | mPa · s | 1 | 1 | 1 | 0.5 | 0.5 | 0.5 | 0.5 | 0.5 | 0.5 |

| | | | | | | | | | |
|---|---|---|---|---|---|---|---|---|---|
| co - (methylhydrogen) | | | | | | | | | |
| siloxane Crosslinker B) | | | | | | | | | |
| with 7 mmol SiH/g | | | | | | | | | |
| UV Cat C1) | 4 | 4 | 4 | | | | | | |
| UV Cat PreMix C2) | | | | 0.3 | 0.3 | 0.3 | 0.3 | 0.3 | 0.3 |
| Total sum parts by weight | 100 | 100 | 100 | 100 | 100 | 100 | 100 | 100 | 100 |
| Viscosity [Pa · s] @ 20° C., | N/A | N/A | N/A | 413 | 162 | 104 | 145 | 198 | 290 |
| 10 s⁻¹, (plate/plate) | | | | | | | | | |
| Width of UV cured dam (mm) | 1.80 | 1.36 | 1.09 | 2.09 | 2.946 | 3.195 | 2.604 | 2.134 | 2.03 |
| Height of UV cured dam (mm) | 1.169 | 1.07 | 0.894 | 1.56 | 1.304 | 1.205 | 1.249 | 1.332 | 1.38 |
| Aspect Ratio (Height/Width) | 0.65 | 0.79 | 0.82 | 0.75 | 0.44 | 0.38 | 0.48 | 0.62 | 0.68 |
| Hardness [Shore 00 - after | | | | 71 | 72 | 70 | 69 | 68 | 69 |
| UV irradiation 30 sec @ | | | | | | | | | |
| 100 mW/cm² - final hardness | | | | | | | | | |
| measured after 2 min) | | | | | | | | | |

The viscosity is normally measured at 20° C. and at a shear rate D of 10 s⁻¹ except for the viscosities with the symbol “*” indicating that the viscosity is a complex viscosity measured at 20° C. and in oscillation mode as indicated above.

Different compounds A2-1), A2-2a) to A2-2d) were tested in the following irradiation curable silicone compositions (in parts per weight) according to the invention as described in the table 2 below and cured under conditions as described above.

TABLE 2

| | Ex 10 | Ex 11 | Ex 12 | Ex 13 | Ex 14 |
|---|---|---|---|---|---|
| UV Cat pre-mix C2) | 0.1 | 0.1 | 0.1 | 0.1 | 0.1 |
| Linear vinyl terminated | 74.55 | 74.637 | 74.418 | 74.616 | 70.53 |
| polydimethylsiloxane | | | | | |
| A11) 65 Pa · s | | | | | |
| linear vinyl terminated | 25 | — | — | — | — |
| dimethyl-co- | | | | | |
| (methyl(vinyl) | | | | | |
| polysiloxane | | | | | |
| A2-2a) with | | | | | |
| 0.024 mmol Si-Vinyl | | | | | |
| (SiVi)/g and complex | | | | | |
| viscosity of 6000 Pa · s | | | | | |
| Linear | — | 25 | — | — | — |
| polydimethylsiloxane | | | | | |
| A2-1)-with complex | | | | | |
| viscosity of 6000 Pa · s | | | | | |
| Linear trimethylsilyl | — | — | 25 | — | — |
| terminated-poly | | | | | |
| ((methyl)(vinyl)siloxane | | | | | |
| A2-2b) with | | | | | |
| 0.116 mmol SiVi/g | | | | | |
| and complex | | | | | |
| viscosity of 6000 Pa · s | | | | | |
| Linear vinyl terminated- | — | — | — | 25 | — |
| polysiloxane A2-2c) | | | | | |
| with 0.0056 mmol | | | | | |
| SiVi/g and | | | | | |
| complex viscosity | | | | | |
| of 6000 Pa · s | | | | | |
| Linear vinyl | — | — | — | — | 25 |
| terminated- | | | | | |
| poly(methylvinyl) co | | | | | |
| (dimethyl)-siloxane | | | | | |
| A2-2d) with | | | | | |
| 1.43 mmol SiVi/g-and | | | | | |
| complex viscosity | | | | | |
| of 3000 Pa · s | | | | | |
| Linear polydimethyl- | 0.35 | 0.263 | 0.482 | 0.284 | 4.37 |
| co-(methylhydrogen) | | | | | |
| siloxane | | | | | |
| Crosslinker B)- | | | | | |
| with 7 mmol | | | | | |
| SiH/ g and a viscosity | | | | | |
| of 40 mPa · s | | | | | |
| Viscosity in Pa · s | 363 | 407 | 366 | 392 | 273 |
| (20° C., shear | | | | | |
| rate 10 s⁻¹) (plate/plate) | | | | | |
| Properties of cured | | | | | |
| silicone compositions | | | | | |
| Hardness Inital | 27 | 8 | 6 | 26 | not |
| (shore 00) | | | | | possible |
| | | | | | to |
| | | | | | measure |
| Hardness final | 57 | 40 | 68 | 59 | 62 |
| (shore 00) | | | | | |
| Aspect Ratio | 0.85 | 0.87 | 0.84 | 0.8 | 0.58 |

In said table 2 above the “initial hardness” refers to the hardness which is measured just two minutes after irradiation. The “final hardness” refers to the hardness measured after one day; i.e. at a point in time when the hardness will remain constant.

The inventors surprisingly found that different kinds of linear polydiorganosiloxane A2-1) or A2-2a) to A2-2c) having a complex viscosity of 6000 Pa·s or 3000 for A2-2d measured at 20° C. and in the oscillation mode, at 25 weight-% in the irradiation curable silicone composition according to the invention could lead to an aspect ratio of the dam above 0.5. The inventive example 14 according to the invention shows some hazing but for application like for sealing application of electronic components, this inventive silicone composition could still be used as the high transparency level is not required for this type of applications.

In the following examples from Ex 15-1 to Ex 15-6, the amount of UV catalyst C2) was added in different amounts. The amount in ppm is related to content of the platinum metal ranging from 6 to 20 ppm Pt. (Table 3)

TABLE 3

| | Ex | Ex | Ex | Ex | Ex | Ex |
|---|---|---|---|---|---|---|
| | 15-1 | 15-2 | 15-3 | 15-4 | 15-5 | 15-6 |
| | 6 ppm Pt | | 10 ppm Pt | | 20 ppm Pt | |
| UV Cat pre-mix C2) | 0.1 | 0.1 | 0.17 | 0.17 | 0.33 | 0.33 |
| Linear vinyl terminated | 84.66 | 84.55 | 84.59 | 84.48 | 84.43 | 84.32 |
| polydimethylsiloxane | | | | | | |
| A11) 65 Pa · s | | | | | | |
| Linear vinyl terminated | 15 | 15 | 15 | 15 | 15 | 15 |
| polydimethylsiloxane | | | | | | |
| A2-2a) with 0.024 | | | | | | |
| millimol Si-Vinyl/g and | | | | | | |
| complex viscosity of | | | | | | |
| 6000 Pa · s at 20° C. | | | | | | |
| Linear dimethyl- | 0.24 | 0.35 | 0.24 | 0.35 | 0.24 | 0.35 |
| co - methylhydrogen | | | | | | |
| siloxane Crosslinker B) | | | | | | |
| with 7 mmol SiH/g and | | | | | | |
| a viscosity of | | | | | | |
| 40 mPa · s at 20° C. | | | | | | |

The irradiation curable silicone compositions according to the invention from Table 3 were used as ready to use one component package for the dam and then they were cured at a UV intensity of below 3 J/cm². The measurements of viscosity of the inventive irradiation curable silicone compositions (as ready to use one component package), the aspect ratio of their cured form and their hardness can be found in Table 4.

TABLE 4

| | Ex | Ex | Ex | Ex | Ex | Ex |
|---|---|---|---|---|---|---|
| | 15-1 | 15-2 | 15-3 | 15-4 | 15-5 | 15-6 |
| Viscosity [Pa · s] at a | 248 | 232 | 235 | 224 | 226 | 228 |
| shear rate D of 10 s⁻¹ | | | | | | |
| at 20° C. (plate/plate) | | | | | | |
| Hardness [Shore 00] | 13 | 45 | 15 | 48 | 12 | 49 |
| Aspect Ratio | 0.63 | 0.63 | 0.62 | 0.62 | 0.62 | 0.61 |
| UV Intensity for curing | <3 | <3 | <3 | <3 | <3 | <3 |
| [J/cm²] | | | | | | |
| Haze⁽¹⁾ | 0.5 | 0.4 | 0.5 | 0.4 | 0.2 | 0.2 |
| Transparency⁽¹⁾ in % | 92.1 | 92.1 | 92.2 | 92.1 | 92.1 | 92.1 |
| Yellowing index (YI) | 0.1 | 0.1 | 0.2 | 0.2 | 0.2 | 0.3 |
| [ASTM E313-73]⁽¹⁾ | | | | | | |

⁽¹⁾= Glass - cured Silicone composition 500 μm thickness - Glass -

From Table 4, the effect of the concentration variation of additives like the UV activatable catalyst C2) and of the SiH crosslinker B) in the inventive silicone compositions Ex 15-1 to Ex 15-6 can be seen on the hardness for the UV cured silicone composition used for the dam according to the invention. All the inventive silicone compositions have a transparency of above 90% and a low yellowing index (below 0.4) after application of the dam and their curing. These properties are very useful for the application in displays.

The different inventive silicone compositions Ex 15-1 to Ex 15-6 were left for 1000 hours at different temperatures from room temperature (25° C.), 40° C. or 100° C. and also at 85° C./85% relative Humidity (r.H). After 1000 hours, the transmittance (%) and the yellowing index (YI) was measured and the results are given in Tables 5a and 5b, respectively.

TABLE 5a

| | | Trans- | Trans- | Transmittance | Trans- |
|---|---|---|---|---|---|
| | Trans- | mittance | mittance | (%) at 85° C./ | mittance |
| | mittance | (%) | (%) at | 85% relative | (%) at |
| | (%) | at RT | 100° C. | Humidity (r.H) | 40° C. |
| Composition/Time | Initial/ | 1000 h | 1000 h | 1000 h | 1000 h |
| Ex 15-1 | 92 | 92 | 92 | 92 | 92 |
| Ex 15-2 | 92 | 92 | 92 | 92 | 92 |
| Ex 15-3 | 92 | 92 | 91 | 91 | 92 |
| Ex 15-4 | 92 | 92 | 91 | 91 | 92 |
| Ex 15-5 | 92 | 92 | 91 | 90 | 92 |
| Ex 15-6 | 92 | 92 | 91 | 90 | 92 |

TABLE 5b

| | Yellow | YI at RT | YI at | YI at 85° C./ | YI at |
|---|---|---|---|---|---|
| | Index (YI) | (25° C.) | 100° C. | 85% r.H | 40° C. |
| Composition/time | Inital | 1000 h | 1000 h | 1000 h | 1000 h |
| Ex 15-1 | 0.1 | 0.1 | 0.4 | 0.3 | 0.2 |
| Ex 15-2 | 0.1 | 0.1 | 0.4 | 0.4 | 0.2 |
| Ex 15-3 | 0.2 | 0.2 | 0.6 | 0.9 | 0.2 |
| Ex 15-4 | 0.2 | 0.2 | 0.5 | 0.9 | 0.2 |
| Ex 15-5 | 0.2 | 0.2 | 0.9 | 1.2 | 0.2 |
| Ex 15-6 | 0.2 | 0.2 | 0.7 | 1.1 | 0.3 |

The inventive irradiation curable silicone compositions Ex 15-1 to-6 are showing a slight increase of the Yellowing Index YI with the increase of temperature or with the presence of 85% relative humidity, but the results for the stability of these inventive one component addition and irradiation curable silicone compositions show that they can be used for long times without losing their properties.

As expected, the inventive irradiation curable silicone compositions Ex 15-5 and Ex 15-6 show the maximum increase in YI in the above conditions. It can be speculated that this is due to the higher amounts of Pt metal from the UV catalyst C2) i.e 20 ppm used in these examples. Preferable concentrations of Pt to be used would be below 20 ppm, preferably below 15 ppm, more preferably up to and including 10 ppm or below 10 ppm.

In order to test the compatibility of the inventive irradiation curable silicone compositions with a LiquideOpticalClearAdhesive (LOCA) material used for displays, the following experiment with InvisiSil® SN 3001 from Momentive (a two-component, high elongation silicone gel used for optical bonding applications, which becomes tack free at room temperature in approximately 30 minutes to a soft, tacky gel with the addition of curing agent) was conducted for each of the inventive irradiation curable silicone compositions Ex 15-1 to 15-6. The dam using one of these inventive silicone composition was first UV cured. The composition of Ex 15-1 for example was dispensed on a glass at a thickness of about 1 mm and UV cured with a metal halide lamp Panacol UV H255 (3J/cm²). The product InvisiSil® SN3001 used as LOCA material was applied on top and covered with a second glass. The samples stack was allowed to stay for one day at room temperature. The samples were analyzed after ageing (left 1000 h at different temperatures RT (25° C.), 40° C., 100° C. or 85° C./85% relative Humidity) to determine whether the dam was visible or not when in the presence of the LOCA (cf. Table 6 below (the rating is as follows: visible with eyes (−) or not visible with eyes (++))

TABLE 6
Appearance after 100 hours at different temperatures of the UV cured
dam (UV cured compositions of Ex 15-1 to 15-6) when applied on glass
and covered by LOCA and another glass substrate

| | Appearance | Appearance | Appearance of | Appearance |
|---|---|---|---|---|
| | of UV | ofUV | UV cured dam | of UV |
| | cured dam | cured dam | −85° C./ | cured dam at |
| | at RT | wt 100° C. | 85% r.H | 40° C. |
| | 1000 h | 1000 h | 1000 h | 1000 h |
| Ex 15-1 | ++ | ++ | ++ | ++ |
| Ex 15-2 | ++ | ++ | ++ | ++ |
| Ex 15-3 | − | − | − | − |
| Ex 15-4 | − | − | − | − |
| Ex 15-5 | − | − | − | − |
| Ex 15-6 | − | − | − | − |

For glass/silicone composition/glass

The irradiation curable silicone compositions according to the invention of Ex 15-1 and 15-2 which are invisible to the eye are suited for display applications (optical bonding)

With higher amount of Pt-catalyst like in Ex 15-5 and 15-6, the dam ring prepared for testing is visible after encapsulation with the product InvisiSil® SN 3001.

These two other compositions would be more suitable for application where there is no need of requirement of invisibility of the dam materials, like in sealants, electronic component/part, board around which the dam is applied etc.

### EMBODIMENTS

1. Irradiation-curable silicone composition, comprising:
   A1) at least one polyorganosiloxane having at least one alkenyl group, preferably two alkenyl groups, with a viscosity up to 500 Pa·s at 20° C. and a shear rate of D=10 s⁻¹,
   A2) at least one linear polydiorganosiloxane, having a complex viscosity of at least 1000 Pa·s, preferably at least 2500, more preferably 5000 Pa·s (measured in the oscillation mode at 20° C.), selected from the group of:
      a linear polydiorganosiloxane having no alkenyl group A2-1) and
      a linear polydiorganosiloxane having at least one alkenyl group bound A2-2) to a silicon atom
   B) at least one polyorganohydrogensiloxane having at least one SiH group, preferably at least two SiH groups, and
   C) at least one irradiation-activatable catalyst,
   D) optionally one or more auxiliary components.
2. Irradiation-curable silicone composition, according to embodiment 1 wherein A1) is at least one linear polydiorganosiloxane of the formula (Ia1),

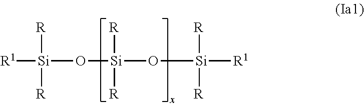

wherein each R is independently selected from saturated or aromatic organic groups, each R¹ is independently selected from alkenyl groups, and x is ≥0,
3. Irradiation-curable silicone composition, according to any of the previous embodiments wherein A2) is at least one linear polydiorganosiloxane of the formula (Ib),

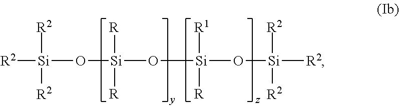

wherein R and R¹ are as defined above; R² is selected from R or R¹, and y is ≥0, and z≥0, Irradiation-curable silicone composition, according to any of the previous embodiments wherein component A2) is a linear polydiorganosiloxane wherein at least one, preferably at least two R² is R¹, preferably R²═R1 is vinyl.
4. Irradiation-curable silicone composition, according to any of the previous embodiments, wherein component A1) comprises at least one polydiorganosiloxane A11) having a viscosity at 20° C. of 5 to 300 Pa·s, preferably of 10 to 200 Pa·s, more preferably 20 to 150 Pa·s.
5. Irradiation-curable silicone composition, according to any of the previous embodiments, wherein component A1) comprises at least one polydiorganosiloxane A12) having a viscosity at 20° C. of less than 5 Pa·s, preferably of 0.1 to 3 Pa·s, more preferably 0.2 to 2 Pa·s.
6. Irradiation-curable silicone composition, according to any of the previous embodiments, wherein component A1) comprises at least one polydiorganosiloxane A11) and at least one polydiorganosiloxane A12).
7. Irradiation-curable silicone composition, according to any of the previous embodiments, wherein component A2) has a complex viscosity at 20° C. and in the oscillation mode of at least 1000 Pa·s, preferably the complex viscosity is in the range of 1000 to 15000 Pa·s, preferably 2500 to 10000 Pa·s, more preferably 3000 to 8000 Pa·s.
8. Irradiation-curable silicone composition, according to any of the previous embodiments, wherein the said silicone composition has a viscosity of at least 150 Pa·s, preferably at least 175 Pa·s, more preferably at least 200 Pa·s at 20° C. and a shear rate of D of 10 s⁻¹.
9. Irradiation-curable silicone composition, according to any of the previous embodiments, wherein the said silicone composition has a viscosity of at most 700 Pa·s at 20° C. and a shear rate of D of 10 s⁻¹.
10. Irradiation-curable silicone composition, according to embodiments 2 to 10, wherein component A11) has in formula la) a value of x being 200 to 2000, preferably 500 to 1200.
11. Irradiation-curable silicone composition, according to any one of embodiments 3 to 11 wherein component A2) has in formula lb) a value of y being 2500 to 10000, preferably 3000 to 8000.
12. Irradiation-curable silicone composition, according to any one of embodiments 3 to 12, wherein component A2) has in formula lb) a value of z being 0 to 350, preferably 0 to 250, more preferably 0 to 50.
13. Irradiation-curable silicone composition, according to any of the previous embodiments, comprising at least 5 weight-%, preferably at least 8 weight-%, more preferably at least 12 weight-%, still more preferably at least 15 weight-% of the component A2), based on the total amount of the composition.
14. Irradiation-curable silicone composition, according to any one of embodiments 5 to 14, comprising at least 50 weight-%, preferably at least 60 weight-%, more preferably at least 70 weight-% of the component A11), based on the total amount of the composition.
15. Irradiation-curable silicone composition, according to any one of embodiments 6 to 15, comprising ≥ 0 to less than 5 weight-%, preferably less than 3 weight-%, more preferably less than 2 weight-% of the component A12), based on the total amount of the composition.
16. Irradiation-curable silicone composition, according to any one of embodiments 5 to 16, comprising, based on 100 parts by weight of the total of A11) and A2), 50 to 95 parts by weight of A11) and 5 to 50 parts by weight of A2), preferably 60 to 90 parts by weight of A11) and 10 to 40 parts by weight of A2), more preferably 70 to 85 parts by weight of A11) and 15 to 35 parts by weight of A2).
17. Irradiation-curable silicone composition, according to any one of embodiments 6 to 17, comprising based on 100 parts by weight of the total of A11) and A2):
   0 to 5 parts by weight of the component A12),
   0.01 to 20 parts by weight of component B),
   1 to 100 ppm of component C) based on A and B), and
   0 to 10 parts by weight of at least one component D).
18. Irradiation-curable silicone composition, according to any of the previous embodiments, comprising less than 3 weight-% of a filler, preferably less than 1% of a filler, more preferably no filler.
19. Irradiation-curable silicone composition, according to any of the previous embodiments, comprising less than 3 weight-% of a resinous polyorganosiloxane having at least one siloxy group selected from T (or RSiO_{3/2}) and Q groups (or SiO_{4/2}), preferably less than 1% of said resinous polyorganosiloxane, more preferably no said resinous polyorganosiloxane.
20. Irradiation-curable silicone composition, according to any of the previous embodiments, wherein the irradiation-activatable catalyst C) is selected from organometallic platinum compounds, preferably from optionally substituted cyclopentadienyl platinum compounds, most preferably component C) is trimethyl (methylcyclopentadienyl)-platinum (IV).
21. Irradiation-curable silicone composition, according to any of the previous embodiments, wherein the component B) is selected from linear polyorganohydrogensiloxanes, preferably having SiH groups in the non-terminal siloxy units thereof, such as

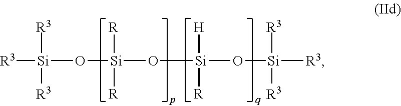

wherein R is as defined above, and R3 is selected from R and H, and p≥0 and q≥1.
22. Irradiation-curable silicone composition, according to any of the previous embodiments, wherein component D) is selected from the group of reinforcing fillers, non-reinforcing filler etc. . . . and mixtures thereof, preferably a non-reinforcing filler.
23. Cured compositions produced by the curing of silicone compositions according to any previous embodiments by UV light at a wavelength selected from 100 to 500 nm.
24. Cured compositions according to embodiment 23 having an aspect ratio (=height/width) of at least 0.5.
25. Cured compositions obtained by irradiation curing of the silicone composition according to any previous embodiments.
26. Cured compositions according to embodiment 24 or 25 having a Shore Hardness Penetration of 35 to 70 and Shore 00 of 5 to 70 (the Shore hardness Penetration being measured according to the norm DIN ISO 2137 and the Shore hardness 00 being measured in accordance to ASTM D2240-02b).
27. Cured compositions according to embodiment 24 having a transparency ≥ 65%.
28. Use of the silicone compositions according to any previous embodiments as dam and sealing material in optical bonding for electronic components.
29. Displays or sealants comprising the cured silicone compositions according to embodiment 24 or 25.

1. An irradiation-curable silicone composition, comprising:
A1) at least one polyorganosiloxane having at least one alkenyl group, preferably two alkenyl groups, with a viscosity up to 500 Pa·s at 20° C. and a shear rate of D=10 s⁻¹,
A2) at least one linear polydiorganosiloxane, having a complex viscosity of at least 1000 Pa·s, preferably at least 2500, more preferably 5000 Pa·s (measured in the oscillation mode at 20° C.), selected from the group of:
a linear polydiorganosiloxane having no alkenyl group A2-1) and
a linear polydiorganosiloxane having at least one alkenyl group bound to a silicon atom A2-2)
B) at least one polyorganohydrogensiloxane having at least one SiH group, preferably at least two SiH groups, and
C) at least one irradiation-activatable catalyst,
D) optionally one or more auxiliary components.

2. Irradiation-curable silicone composition, according to claim 1 wherein A1) is at least one linear polydiorganosiloxane of the formula (Ia1), 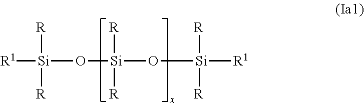
wherein each R is independently selected from saturated or aromatic organic groups, each R¹ is independently selected from alkenyl groups, and x is ≥0.

3. Irradiation-curable silicone composition, according to claim 1 wherein A2) is at least one linear polydiorganosiloxane of the formula (Ib), 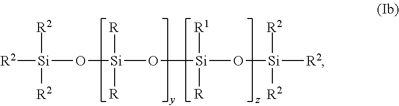
wherein R and R¹ are as defined above; R² is selected from R or R¹, and y is ≥0, and z≥0.

4. Irradiation-curable silicone composition, according to claim 1 wherein component A2) is a linear polydiorganosiloxane wherein at least one, preferably at least two R² is R¹, preferably R²═R1 is vinyl.

5. Irradiation-curable silicone composition, according to claim 1, wherein component A1) comprises at least one polydiorganosiloxane A11) having a viscosity at 20° C. of 5 to 300 Pa's, preferably of 10 to 200 Pa·s, more preferably 20 to 150 Pa·s.

6. Irradiation-curable silicone composition, according claim 1, l wherein component A1) comprises at least one polydiorganosiloxane A12) having a viscosity at 20° C. of less than 5 Pa·s, preferably of 0.1 to 3 Pa's, more preferably 0.2 to 2 Pa·s.

7. Irradiation-curable silicone composition, according to claim 1, wherein component A1) comprises at least one polydiorganosiloxane A11) and at least one polydiorganosiloxane A12).

8. Irradiation-curable silicone composition, according to claim 1, wherein component A2) has a complex viscosity at 20° C. and in the oscillation mode of at least 1000 Pa·s, preferably the complex viscosity is in the range of 1000 to 15000 Pa's, preferably 2500 to 10000 Pa·s, more preferably 3000 to 8000 Pa's.

9. Irradiation-curable silicone composition, claim 1, wherein the said silicone composition has a viscosity of at least 150 Pa's, preferably at least 175 Pa·s, more preferably at least 200 Pa's at 20° C. and a shear rate of D of 10 s⁻¹ and/or
has a viscosity of at most 700 Pa·s at 20° C. and a shear rate of D of 10 s⁻¹.

10. The irradiation-curable silicone composition, according to claim 5, wherein component A11) has in formula la) a value of x being 200 to 2000, preferably 500 to 1200.

11. The irradiation-curable silicone composition, according to claim 3 wherein component A2) has in formula Ib) a value of y being 2500 to 10000, preferably 3000 to 8000,
and a value of z being 0 to 350, preferably 0 to 250, more preferably 0 to 50.

12. The irradiation-curable silicone composition, according to previous claim 1, wherein the component B) is selected from linear polyorganohydrogensiloxanes, preferably having SiH groups in the non-terminal siloxy units thereof, such as 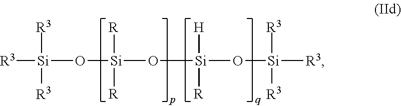
wherein R is as defined above, and R³ is selected from R and H, and p≥0 and q≥1.

13. A cured silicone composition produced by the curing of silicone compositions according to claim 1 by UV light at a wavelength selected from 100 to 500 nm.

14. A dam and sealing material for optical bonding of an electronic component comprising the silicone compositions according to claim 1.

15. A display or sealant comprising the cured silicone composition according to claim 13.
